(19) United States
(12) Patent Application Publication
(10) Pub. No.: US 2026/0023098 A1
(43) Pub. Date: Jan. 22, 2026

(54) TEST JIG

(71) Applicant: Fulian Precision Electronics (Tianjin) Co., LTD., Tianjin (CN)

(72) Inventors: WEI-MING LEE, New Taipei (TW); Chi-Wen Chen, New Taipei (TW)

(21) Appl. No.: 18/962,139

(22) Filed: Nov. 27, 2024

(30) Foreign Application Priority Data
Jul. 19, 2024 (CN) 202410972983.9

(51) Int. Cl. G01R 1/04

(52) U.S. Cl. CPC G01R 1/0416

(57) ABSTRACT

A test jig includes a first port, a second port, a measurement conductor, a current transformer, and a current output port. A first end of the first port is electrically connected to a first device. A first end of the second port is electrically connected to a second device. Two ends of the measurement conductor are connected with a second end of the first port and a second end of the second port respectively. The current transformer is electrically connected with the measurement conductor in parallel. The current output port is electrically connected to an output end of the current transformer and is configured to output a to-be-tested current. A test efficiency of the test jig is improved.

### TECHNICAL FIELD

The present application generally relates to test technology, and particularly to a test jig.

### BACKGROUND

With a development in technologies, such as artificial intelligence, demands of servers in market increases massively. In current, as the number of the servers disposed in a server cabinet increasing, when a traditional method for detecting currents or voltages is used for testing or detecting, plug-connection operations by technology persons between the server cabinet and the servers are numerous and complex, it will cause a time cost and a labor cost to be increased while testing.

There is room for improvement in the art.

### BRIEF DESCRIPTION OF THE DRAWINGS

Implementations of the present application will now be described, by way of example only, with reference to the attached figures.

FIG. 1 is a diagram illustrating an embodiment of an application environment of a test jig according to the present application.

FIG. 2 is a diagram illustrating an embodiment of a test jig according to the present application.

FIG. 3 is a partially exploded diagram illustrating the test jig of FIG. 1 according to the present application.

FIG. 4 is a diagram illustrating a first connection manner of the test jig according to the present application.

FIG. 5 is a diagram illustrating a second connection manner of the test jig according to the present application.

### DETAILED DESCRIPTION

The following clearly describes the technical solution in embodiments of this application with reference to the accompanying drawings in the embodiments of the application.

It should be noted that, when a component is considered to be “connected” to another component, it can be directly connected to the another component or an intermediate element may exist therebetween. When a component is considered as to be “fixed” to another component, it can be directly on the another component or an intermediate element may exist therebetween. The terms used in the present application, such as “top”, “bottom”, “up”, “down”, “left”, “right”, “front”, “rear” and similar expressions used herein are for illustrative purposes only, and do not represent unique embodiments.

Unless otherwise defined, meanings of all technical and scientific terms used in the present application are the same as the those generally understood by persons skilled in the art of the present application. The terms used in the specification of the present application herein are used only to describe specific embodiments, and not intended to limit the preset application.

The following describes in detail some implementation of the present application with reference to the accompanying drawings. Under a condition that no conflict occurs, the following embodiments and features in the embodiments may be mutually combined.

Therefore, the present application provides a test jig, which simplifies manual operations, for improving a test efficiency and reducing a test cost.

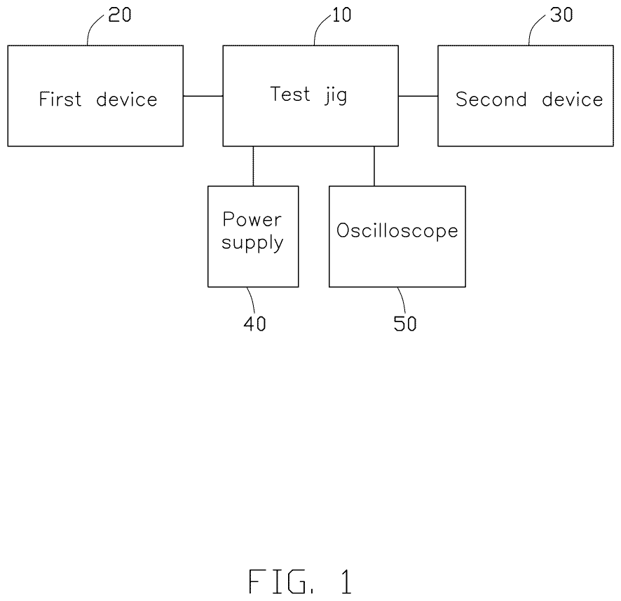

Referring to FIG. 1, FIG. 1 shows an application environment of the test jig 10. The test jig 10 is suitable to acquire a current and a voltage outputted by a first device 20, which are provided to a second device 30, for assisting technology persons to repair or service the first device 20 or the second device 30. To more clearly illustrate the test jig 10 provided by the present application, the following uses an example in which the first device 20 is a power shelf, and the second device 30 is a server. It is understood that, in other embodiments, the test jig 10 also can be applied in other devices. The present application does not limit the types of the first device 20 and the second device 30. For example, the first device 20 also may be a server cabinet, and the second device 30 also may be a power shelf.

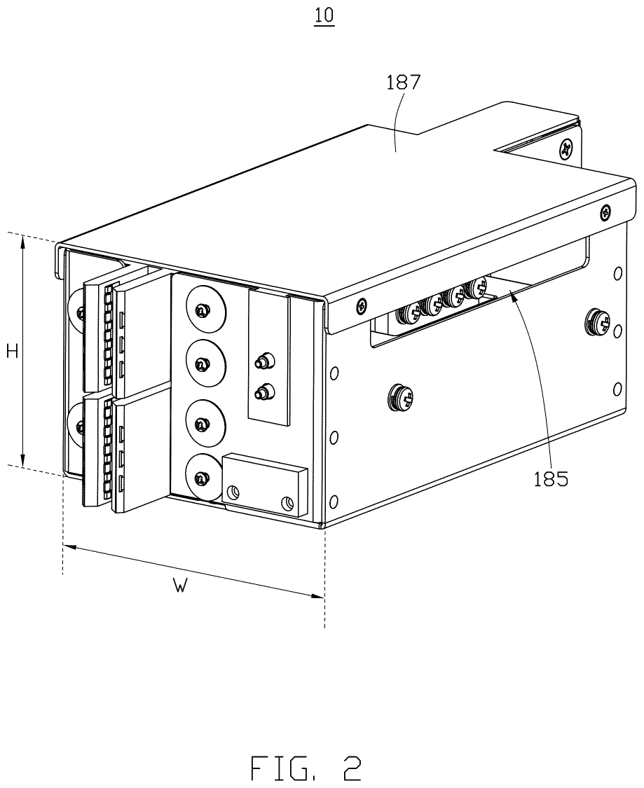

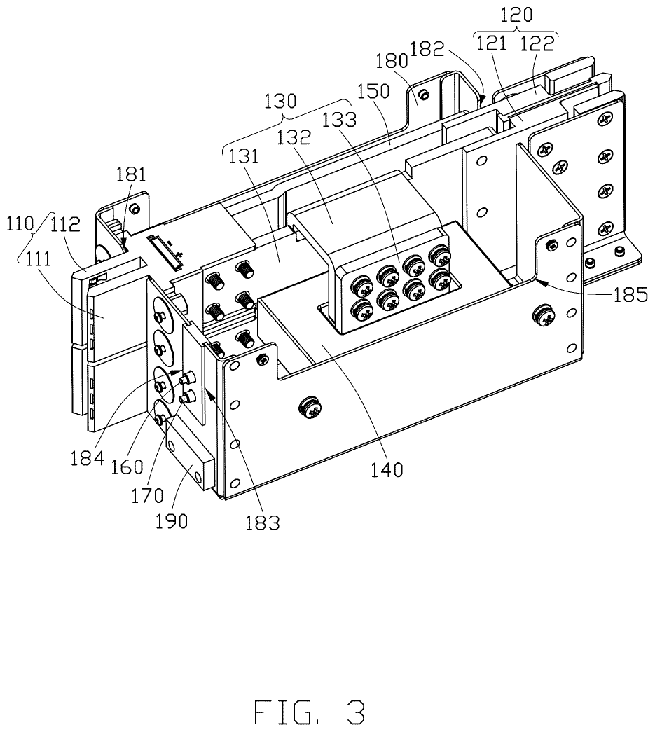

Referring to FIGS. 2 and 3 together, the test jig 10 includes a first port 110, a second port 120, a measurement conductor 130, a current transformer 140, and a current output port 160.

A first end of the first port 110 is electrically connected to the first device 20. A first end of the second port 120 is electrically connected to the second device 30. Two ends of the measurement conductor 130 are electrically connected to a second end of the first port 110 and a second end of the second port 120 respectively. The current transformer 140 is electrically connected to the measurement conductor 130 in parallel. The current output port 160 is electrically connected to an output end of the current transformer 140, and is configured to output a to-be-tested current.

The first port 110 includes a first positive terminal 111 and a first negative terminal 112. The second port 120 includes a second positive terminal 121 and a second negative terminal 122. The measurement conductor 130 is electrically connected between the first positive terminal 111 and the second positive terminal 121. The test jig 10 further includes a negative conductor 150. The negative conductor 150 is electrically connected between the first negative terminal 112 and the second negative terminal 122.

Further, the measurement conductor 130 includes a first piece 131, a second piece 132, and a third piece 133. The an edge of the first piece 131 extends a distance along a direction away from a sidewall of the first piece 131 to form the second piece 132. An end of the second piece 132 away from the first piece 131 bends and extends a distance to form the third piece 133. The first piece 131, the second piece 132, and the third piece 133 are substantially in rectangular shaped. The second piece 132 is substantially perpendicular to the first piece 131. The third piece 133 is substantially perpendicular to the second piece 132, and is substantially parallel to the first piece 131. Two ends of the first piece 131 are connected to the first positive terminal 111 of the second end of the first port 110 and the second positive terminal 121 of the second endo of the second port 120 respectively. The current transformer 140 is electrically connected with the third piece 133 in parallel.

The negative conductor 150 is substantially in a rectangular shaped. The negative conductor 150 is parallel with the first piece 131. The negative conductor 150 is disposed on a side of the first piece 131 away from the second piece 132 and the third piece 133.

It is understood that, the current transformer 140 is a device for converting a high current of a side into a small current in another side to measure based on an electromagnetic induction principle.

It is understood that, by setting the first piece 131 to be connected between the first positive terminal 111 and the second positive terminal 121, in comparing with a normal conductor wire, the test jig 10 may experience higher currents, for example, the current up to 1200 A. Further, based on a three-section design of the measurement conductor 130, it is suitable to servers in small volume. In detail, referring to FIG. 1 again, in the present application, based on the three-section design of the measurement conductor 130, a height H of the test jig 10 is 91.29 millimeter, and a width W (a width of a side where the first port 110 or the second port 120 are disposed) of the test jig 10 is 155.98 millimeter, therefore the structure of the test jig 10 is suitable to the server cabinet in 2 Open Units (2 OU) height or above 2 OU.

In some embodiments, one of the first port 110 and the second port 120 is a chip connector, and another of the first port 110 and the second port 120 is a busbar (also called as a busbar connector). Thus, the test jig 10 is directly plugged with the first device 20 or the second device 30 through the first port 110 or the second port 120, for quickly assembling. For example, the chip connector may be directly plugged with the busbar of the cabinet, the busbar may be directly plugged with the server or the power shelf.

In some embodiments, the test jig 10 further includes a voltage output port 170. The voltage output port 170 is connected to the first port 110 and the second port 120, and is configured to output a to-be-tested voltage.

In some embodiments, the test jig 10 further includes a housing 180 with openings at a sidewall. Opposite sides of the housing 180 define a first notch 181 and a second notch 182 respectively. The first port 110 is disposed in the first notch 181, and the second port 120 is disposed in the second notch 182. The measurement conductor 130, the negative conductor 150, and the current transformer 140 are disposed in the housing 180.

The housing 180 further defines a receiving slot 183. The receiving slot 183 is configured to receive an insulation component 184. The current output port 160 and the voltage output port 170 are disposed on the insulation component 184. In some embodiments, the current output port 160 and the voltage output port 170 are Sub Miniature version B (SMB) connectors. Therefore, interfaces of the oscilloscope 50 are connected to the current output port 160 and the voltage output port 170, and the waveforms of the current output port 160 and the voltage output port 170 are displayed on the oscilloscope 50. It is understood that, by setting the insulation component 184 on the housing 180, the current output port 160 and the voltage output port 170 are disposed on the insulation component 184, a short-circuit probability of the test jig 10 is reduced.

The test jig 10 further includes a power port 190. The power port 190 is electrically connected to a power input terminal of the current transformer 140. The power port 190 is configured to connect to the power supply 40, for receiving electrical energy outputted by the power supply 40 to power the current transformer 140.

In some embodiments, two other opposite sides of the housing 180 define heat dissipation slots 185 (as shown in FIG. 2) for increasing a heat dissipation speed of the test jig 10.

In some embodiments, the test jig 10 further includes a cover 187 (as shown in FIG. 2). The cover 187 is covered on the opening of the housing 180, which has effects of dustproofing and waterproofing, thus a fault probability of the test jig 10 is reduced.

Based on the above, the test jig 10 provided by the present application, sets with the first port 110 and the second port 120 for being quickly plugged with the first device 20 and the second device 30, a test efficiency is improved. Further, the measurement conductor 130 on the test jig 10 is designed in the three-section, thus the test jig 10 is more suitable to apply with the servers with smaller volume.

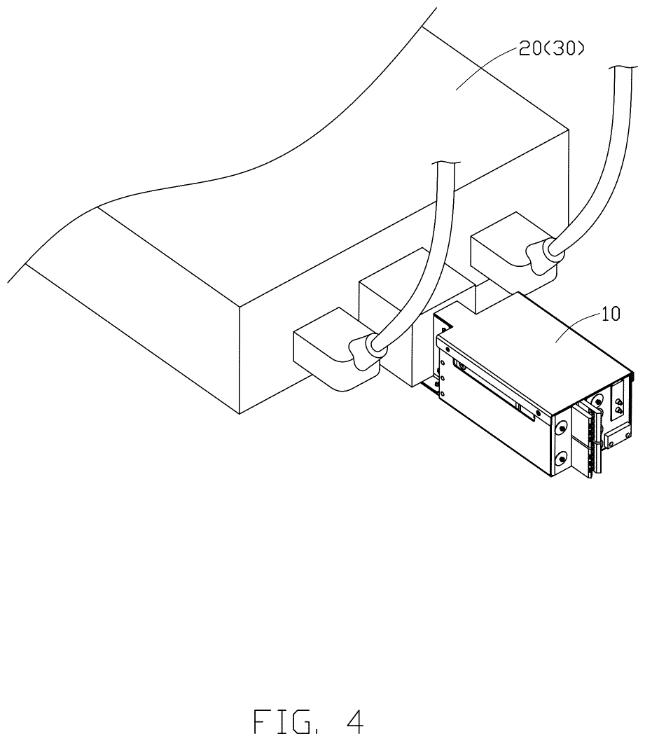

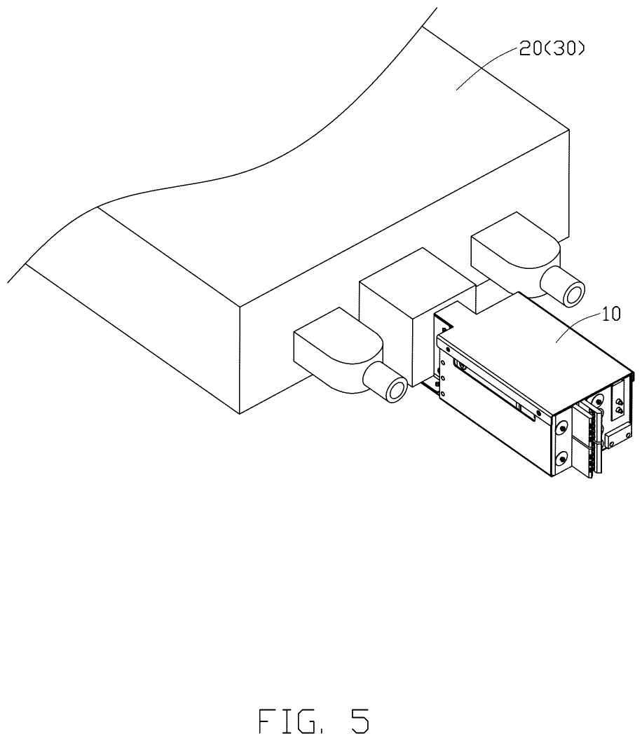

Referring to FIGS. 4 and 5, FIG. 4 shows the second port 120 of a first embodiment of the present application being plugged with the first device 20. FIG. 5 shows the second port 120 of a second embodiment of the present application being plugged with the second device 30. As shown in FIGS. 4 and 5, the test jig 10 provided by the present application is sufficiently small, and is suitable to configure different devices with different types of a power cable. The test jig 10 is flexibly plugged with a to-be-tested device (such as the first device 20 or the second device 30).

Furthermore, it should be noted that the above accompanying drawings are only schematic descriptions of the processes included in the methods according to the exemplary embodiments of the present application, and are not intended to limit.

The present application is not limited to the above specific embodiments. Those skilled in the art will easily understand that there are many alternatives to the test jig 10 of the present application without departing from the principles and scope of the present application. The scope of the present application is subject to the contents of the claims.

What is claimed is:

1. A test jig comprises:
a first port, a first end of the first port configured to connect to a first device;
a second port, a first end of the second port configured to connect to a second device;
a measurement conductor, two ends of the measurement conductor are connected with a second end of the first port and a second end of the second port respectively;
a current transformer, electrically connected with the measurement conductor in parallel; and
a current output port, electrically connected with an output end of the current transformer and configured to output a to-be-test current.

2. The test jig of claim 1, wherein the measurement conductor comprises a first piece, a second piece, and a third piece; an edge of the first piece extends a distance along a direction away from a sidewall of the first piece to form the second piece; an end of the second piece away from the first piece bends and extends a distance to form the third piece.

3. The test jig of claim 2, wherein two ends of the first piece are connected to the second end of the first port and the second end of the second port; the current transformer is electrically connected with the third piece in parallel.

4. The test jig of claim 3, wherein the first port comprises a first positive terminal; the second port comprises a second positive terminal; two ends of the first piece are connected to the first positive terminal of the second end of the first port and the second positive terminal of the second end of the second port respectively.

5. The test jig of claim 1, wherein the one of the first port and the second port is a chip connector, and another of the first port and the second port is a busbar.

6. The test jig of claim 1, wherein the test jig further comprises a voltage output port; the voltage output port is connected to the first port and the second port, and is configured to output a to-be-tested voltage.

7. The test jig of claim 6, wherein the current output port and the voltage output port are Sub Miniature version B (SMB) connectors.

8. The test jig of claim 1, wherein the test jig further comprises a power port; the power port is electrically connected to a power input terminal of the current transformer; the power port is configured to connect to the power supply.

9. The test jig of claim 7, wherein the test jig further comprises a housing with openings at a sidewall; opposite sides of the housing define a first notch and a second notch respectively; the first port is disposed in the first notch, and the second port is disposed in the second notch; the measurement conductor and the current transformer are disposed in the housing.

10. The test jig of claim 9, wherein the housing defines a receiving slot; the receiving slot configured to receive an insulation component; the current output port and the voltage output port are disposed on the insulation component.
